(19) United States
(12) Patent Application Publication
(10) Pub. No.: US 2005/0231923 A1
(43) Pub. Date: Oct. 20, 2005

(54) Ejector for motherboard

(75) Inventors: Wen-Tang Peng, Tu-Cheng (TW); Cheng-Lung Cheng, Tu-Cheng (TW); Shu-Gang Shi, Shenzhen (CN); Zhe Zhang, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/070,791

(22) Filed: Mar. 2, 2005

(30) Foreign Application Priority Data
Apr. 17, 2004 (CN) 200420045007.7

(51) Int. Cl. H05K 5/02

(52) U.S. Cl. 361/754

(57) ABSTRACT

An ejection assembly as shown is used for rapidly ejecting a motherboard (10) from a server chassis (20). The ejection assembly includes a tray (30) for supporting the motherboard, and an ejector (40). A connector (22) is disposed in the chassis. The ejector is pivotally mounted to the tray, and includes an ejecting portion (48) to abut against a front edge of a bottom plate (24) of the chassis when the motherboard is electronically connected to the connector of the chassis. The ejector is pivoted outwardly so that the ejecting portion presses the front edge of the bottom plate to draw the tray outwardly, the motherboard is thereby horizontally and rapidly ejected from the connector of the chassis.

### BACKGROUND OF THE INVENTION

1. Field of the Invention

The present invention relates to an ejector for a motherboard, and particularly to an ejector which can readily eject a motherboard from a chassis without damaging the motherboard.

2. Description of the Prior Art

Generally, a personal computer or a server has limited inner space, therefore a printed circuit board is usually horizontally connected with a connecter. An example is disclosed in China Patent No. 02247527.3. A memory of this patent is horizontally connected with a connector of a motherboard. The connector includes an elongated main body and two locking portions secured to opposite sides of the main body. The memory is inserted to the connector and secured by the locking portions. The locking portions must be pulled outwardly, then the memory is manually taken out. This manner is suitable for a small printed circuit board connected to a connector. However, when disengaging a large printed circuit board such as a motherboard from a connector, pulling out the locking portions is a tough work in a narrow inner space of the personal computer or server. Furthermore, pulling out the motherboard with manual work can not guarantee the pulling force being parallel to the motherboard. Therefore, the motherboard and the connecter are prone to be damaged.

Thus, an improved ejector for ejecting a motherboard from a chassis is desired.

### BRIEF SUMMARY OF THE INVENTION

Accordingly, an object of the present invention is to provide an ejector for rapidly ejecting a printed circuit board from a connector of a computer chassis.

A further object of the present invention is to provide an ejector for smoothly disengaging a printed circuit board from a connector of a computer chassis without damaging the printed circuit board and the connector.

To achieve the above-mentioned objects, an ejection assembly in accordance with a preferred embodiment of the present invention is used for rapidly ejecting a motherboard from a server chassis. The ejection assembly includes a tray for supporting the motherboard, and an ejector. A connector is disposed in the chassis. The ejector is pivotally mounted to the tray, and includes an ejecting portion to abut against a front edge of a bottom plate of the chassis when the motherboard is electronically connected to the connector of the chassis. The ejector is pivoted outwardly so that the ejecting portion presses the front edge of the bottom plate to draw the tray outwardly, the motherboard is thereby horizontally and rapidly ejected from the connector of the chassis without damaging the connector and the motherboard.

Other objects, advantages and novel features of the present invention will be drawn from the following detailed description of preferred embodiments of the present invention with the attached drawings, in which:

### BRIEF DESCRIPTION OF THE DRAWINGS

FIG. 1 is an exploded, isometric view of an electronic assembly in accordance with the present invention, the electronic assembly including a chassis, a motherboard, and an ejector;

FIG. 2 is an assembled, isometric view of FIG. 1, showing the motherboard in an insertion position;

FIGS. 3 and 4 are enlarged views of the circled portions III and IV of FIG. 2, respectively;

FIG. 5 is an assembled, isometric view of FIG. 2, showing the motherboard in an ejection position; and

FIGS. 6 and 7 are enlarged views of the circled portions VI and VII of FIG. 5, respectively.

### DETAILED DESCRIPTION OF THE INVENTION

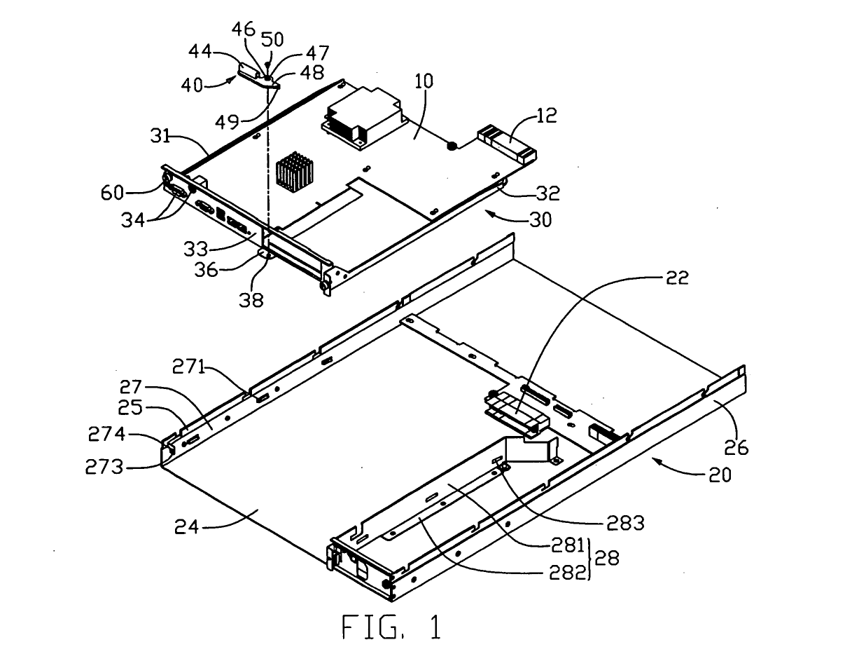

Referring to FIG. 1, an ejection assembly for an electronic device like a server in accordance with a preferred embodiment of the present invention is used for rapidly ejecting a printed circuit board such as a motherboard 10 from a server chassis 20. The ejection assembly comprises a motherboard tray 30, and an ejector 40.

The motherboard 10 has a horizontal connecting portion 12 at a rear end thereof. The chassis 20 comprises a bottom plate 24, a left side plate 25, and a right side plate 26. An elongated board 27 is mounted to an inner surface of the left side plate 25. A plurality of bent tabs 271 is stamped inwardly from the elongated board 27. A blocking tab 273 is bent inwardly from a front portion of the elongated board 27 with a threaded hole 274 defined therein. A connector slot 22 is disposed in the chassis 20 corresponding to the connecting portion 12 of the motherboard 10. A partition plate 28 is mounted on the bottom plate 24 of the chassis 20 in the vicinity and parallel to the right side plate 26. The partition plate 28 comprises a mounting portion 282 and an upright portion 281 extending upright from the mounting portion 282. A plurality of bent tabs 283 is stamped inwardly from the upright portion 281.

The motherboard tray 30 is used for supporting the motherboard 10, and comprises a left guiding plate 31 and a right guiding plate 32 at opposite sides thereof. The left and right guiding plate 31, 32 corporate with the bent tabs 271, 283 to guide the tray 30 into the chassis 20 and restrict the tray 30 in a vertical direction and a left-to-right direction. A front plate 33 is formed at a front portion of the tray 30. The front plate 33 has a thumb-screw 60 mounted thereto and defines a plurality of openings 34 for accommodating frontal connectors of the motherboard 10. A horizontal locking tab 36 is formed outwardly from the front plate 33. A threaded aperture 38 is defined in the locking tab 36. The ejector 40 comprises a locking portion 46 having an arc profile, a handle portion 44 which is bent upwardly to form a U-shaped cross section, and an ejection portion 48 forming an ejection tab 49 downwardly. A pivot hole 47 is defined in the locking portion 46. A screw 50 extends through the pivot hole 47 of the ejector 40 and then engages in the threaded aperture 38 of the locking tab 36, the ejector 40 is thereby pivotally secured to the locking tab 36.

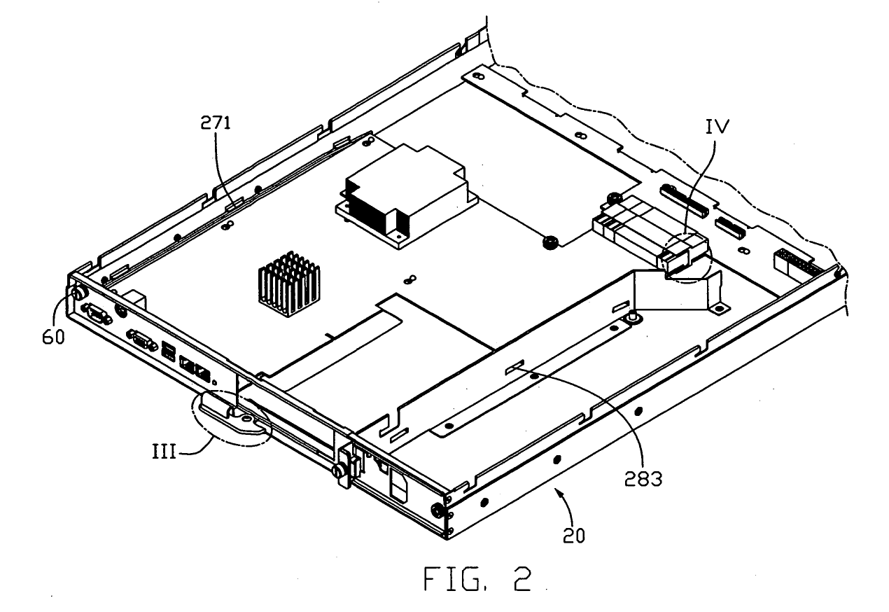

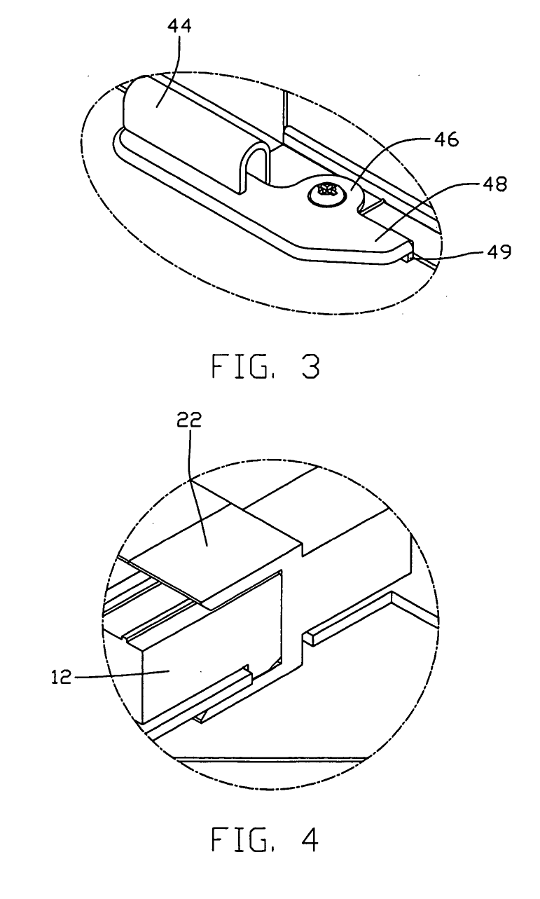

Referring also to FIGS. 2-4, in assembly, the motherboard tray 30 together with the motherboard 10 and the ejector 40 is horizontally placed to the chassis 20. The tray 30 is then horizontally pushed into the chassis 20 until the connecting portion 12 of the motherboard 10 is entirely inserted into the connector slots 22. At this time, the ejecting tab 49 of the ejector 40 abuts against a front edge of the bottom plate 24, and the front plate 33 of the tray 30 abuts against the blocking tab 273 of the chassis 20 to prevent the motherboard 10 from further insertion. The thumb-screw 60 is then pivoted to secure the motherboard 10 to the blocking tab 273 of the chassis 20.

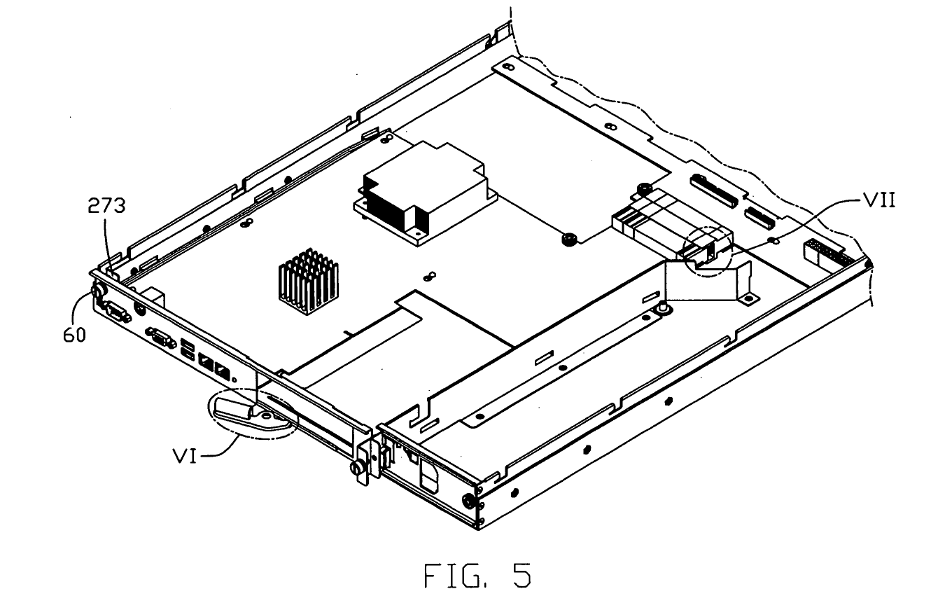

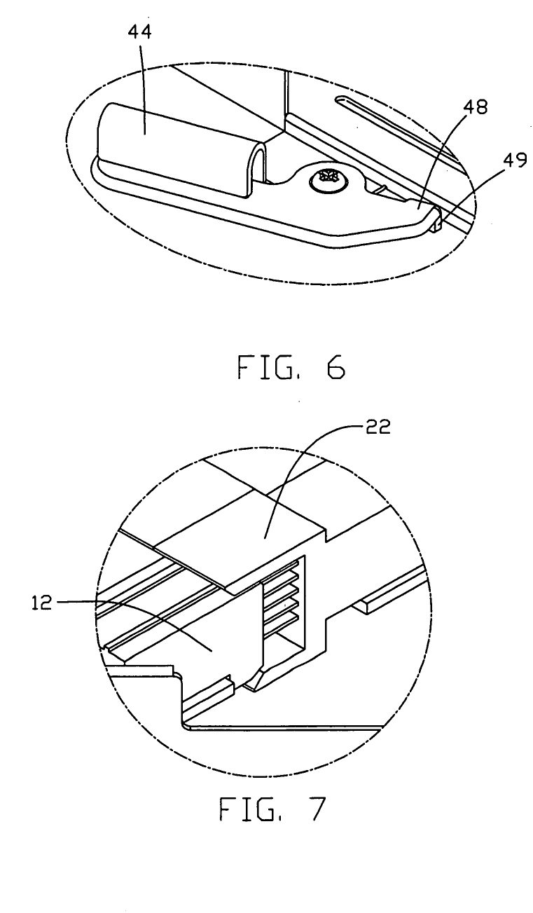

Referring also to FIGS. 5-7, in ejecting the motherboard 10 from the chassis 20, the thumb-screw 60 is unscrewed from the blocking tab 273. The handle portion 44 of the ejector 40 is rotated outwardly, so that the ejecting tab 49 of the ejector 40 presses a front edge of the bottom plate 24 to draw the motherboard 10 outwardly. Because the elongated board 27, the partition plate 28, and the bent tabs 271, 283 corporately restrict the motherboard 10 in a horizontal direction and being parallel to the connector slot 22, the connecting portion 12 and the connector slot 22 are prevented from being damaged.

The above-mentioned drawing means can also be applied to a personal computer to draw a printed circuit board from a connected of the computer chassis.

It is understood that the invention may be embodied in other forms without departing from the spirit thereof. Thus, the present examples and embodiments are to be considered in all respects as illustrative and not restrictive, and the invention is not to be limited to the details given herein.

1. An assembly comprising:
a chassis comprising a bottom plate and two side plates, a connector being disposed at a rear portion of the chassis;
a tray for supporting a motherboard, the tray slidably disposed in the chassis; and
an ejector pivotally mounted to the tray, the ejector comprising an ejecting portion to abut against a front edge of the bottom plate of the chassis when the motherboard is electronically connected to the connector of the chassis;
wherein the ejector is pivoted so that the ejecting portion presses the front edge of the bottom plate of the chassis to draw the tray outwardly, the motherboard is thereby ejected from the connector of the chassis.

2. The assembly as claimed in claim 1, wherein the ejecting portion of the ejector is further bent downwardly to form an ejecting tab for abutting the front edge of the bottom plate of the chassis.

3. The assembly as claimed in claim 2, wherein the ejector comprises a locking portion defining a pivot hole, a locking tab defining a threaded aperture is formed at a front portion of the tray, a screw extends through the pivot hole and engages in the threaded aperture.

4. The assembly as claimed in claim 3, wherein the ejector further comprises a handle portion having a U-shaped cross section.

5. The assembly as claimed in claim 1, wherein a partition plate is arranged on the bottom plate of the chassis, the partition plate together with one of the side plates restricts the tray.

6. The assembly as claimed in claim 5, wherein a plurality of bent tabs is stamped from said one of the side plates and the partition plate for restricting the motherboard in a direction vertical to the bottom plate.

7. The assembly as claimed in claim 1, wherein the motherboard forms a connecting portion at a rear portion thereof for being inserted in the connector of the chassis, an ejecting direction of the motherboard is parallel with the side plates.

8. The assembly as claimed in claim 7, wherein a fastening member secures the tray to the chassis when the connecting portion of the motherboard is inserted in the connector of the chassis.

9. An assembly comprising:
a chassis having a bottom plate and two opposite parallel plates extending from the bottom plate, a connector disposed in the chassis;
a motherboard tray being sandwiched between and slidable along the parallel plates in a direction perpendicular to the connector;
a motherboard secured to the motherboard tray, and having a connecting portion being inserted in or drawn out from the connector of the chassis in said direction; and
an ejector pivotally attached to the motherboard tray the ejector having an ejecting portion at an end thereof to press the chassis to draw the motherboard tray outwardly in said direction.

10. The assembly as claimed in claim 9, wherein the tray comprises two guiding plates at opposite sides of the motherboard for abutting the parallel plates of the chassis.

11. The assembly as claimed in claim 9, wherein a plurality of bent tabs is stamped from the parallel plates of the chassis for abutting against an upper surface of the motherboard to restrict the motherboard in a vertical direction.

12. The assembly as claimed in claim 9, wherein a blocking tab is formed from a front end of one of the parallel plates for blocking a front plate of the tray.

13. The assembly as claimed in claim 12, wherein a thumb-screw is mounted to the front plate of the tray to engage in a threaded aperture of the blocking tab.

14. The assembly as claimed in claim 9, wherein the ejecting portion of the ejector abuts against a front edge of the bottom plate of the chassis when the connecting portion of the motherboard is inserted in the connector of the chassis.

15. The assembly as claimed in claim 14, wherein the ejecting portion further includes an ejecting tab bent downwardly therefrom to abut against the front edge of the bottom plate.

16. The assembly as claimed in claim 9, wherein a locking tab is formed from a front plate of tray for pivotally attachment of the ejector thereto.

17. A method of managing assembly of an electronic device, comprising:
providing a chassis enclosing said electronic device and having a connector disposed therein;
providing a circuit board having a connecting portion electrically engagable with said connector of said chassis along a predetermined direction;
loading said circuit board in a tray;
installing said tray with said circuit board into said chassis by means of confined movement of said tray in said chassis along said predetermined direction to facilitate electrical engagement of said connector and said connecting portion of said circuit board; and
withdrawing said tray with said circuit board out of said chassis and disconnecting said connector and said connecting portion by means of using a ejector to trigger a reverse confined movement of said tray in said chassis along a reverse direction to said predetermined direction.

18. The method as claimed in claim 17, wherein said confined movement and said reverse confined movement of said tray are achievable by engagement between at least one guiding plate of said tray and a corresponding plate of said chassis in said installing and withdrawing steps respectively.

19. The method as claimed in claim 17, wherein said ejector is attached to said tray and reachable to a front edge of said chassis from an outside of said chassis so as to generate a tray-movement-triggering and disconnecting force by means of engagement of said ejector and said front edge.
